(19) United States
(12) Patent Application Publication
(10) Pub. No.: US 2023/0378054 A1
(43) Pub. Date: Nov. 23, 2023

(54) SEMICONDUCTOR CELL STRUCTURE, INTEGRATED CIRCUIT, AND MANUFACTURING METHOD THEREOF

(71) Applicant: Taiwan Semiconductor Manufacturing Company, Ltd., Hsinchu (TW)

(72) Inventors: Chia-Chung CHEN, Keelung (TW); Wen-Shen CHOU, Zhubei City (TW); Yung-Chow PENG, Hsinchu (TW); Chung-Sheng YUAN, Hsinchu (TW); Yi-Kan CHENG, Taipei City (TW)

(73) Assignee: Taiwan Semiconductor Manufacturing Company, Ltd., Hsinchu (TW)

(21) Appl. No.: 18/150,189

(22) Filed: Jan. 4, 2023

Related U.S. Application Data
(60) Provisional application No. 63/364,804, filed on May 17, 2022.
(60) Provisional application No. 63/380,237, filed on Oct. 20, 2022.

(51) Int. Cl. H01L 23/522; H01L 27/092; H01L 29/423; H01L 29/06; H01L 29/775; H01L 21/8238

(52) U.S. Cl. CPC H01L 23/5226; H01L 27/092; H01L 29/42392; H01L 29/0673; H01L 29/775; H01L 21/823871; G05F 3/262

(57) ABSTRACT

A semiconductor cell structure includes a first complementary metal oxide silicon (CMOS) a second CMOS, a first conducting element, and a second conducting element. The first and second CMOSs are disposed on the substrate and a reference voltage is provided to the first CMOS and the second CMOS respectively through the first conducting element and the second conducting element. A product of a width of the first conducting element multiplied by a channel length of the first CMOS is positively related to a product of a width of the second conducting element multiplied by a channel length of the second CMOS.

### CROSS-REFERENCE TO RELATED PATENT APPLICATIONS

This application claims priority to U.S. Provisional Application No. 63/364,804, filed on May 17, 2022, entitled “Interconnect Layout for A Semiconductor Device,” and U.S. Provisional Application No. 63/380,237, filed on Oct. 20, 2022, entitled “Semiconductor Cell Structure, Integrated Circuit, And Manufacturing Method Thereof,” which all applications are hereby incorporated herein by reference in its entirety.

### BACKGROUND

The recent trend in miniaturizing integrated circuits (ICs) has resulted in increasing design complexity in integrating more semiconductor devices and routings within a smaller area. Semiconductor devices or integrated circuits fabricated by performing lithography processes on both sides of a substrate to have patterned traces disposed on or semiconductor devices mounted on both sides of the substrate can be beneficial to area requirements since power can be provided from the backside of the substrate. However, increased travel distance of power also leads to inconsistent voltage drops for different circuits.

### BRIEF DESCRIPTION OF THE DRAWINGS

Aspects of the present disclosure can be understood from the following detailed description and the accompanying figures. It is noted that, in accordance with the standard practice in the industry, various features are not drawn to scale. In fact, the dimensions of the various features may be arbitrarily increased or reduced for illustration or clarity of discussion.

FIG. 1A illustrates a schematic diagram of an integrated circuit, in accordance with some embodiments.

FIG. 1B illustrates a partial layout of the semiconductor cell structure of the integrated circuit in FIG. 1A, in accordance with some embodiments.

FIG. 1C illustrates a cross-sectional view of a PMOS along section line A-A′ in FIG. 1B, in accordance with some embodiments.

FIG. 1D illustrates a cross-sectional view of a conductive path along a section line B-B′ in FIG. 1B, in accordance with some embodiments.

FIG. 2 illustrates a layout of a semiconductor cell structure, in accordance with some embodiments.

FIG. 3 illustrates a layout of a semiconductor cell structure, in accordance with some embodiments.

FIG. 4 illustrates a layout of a semiconductor cell structure, in accordance with some embodiments.

FIG. 5A illustrates a semiconductor cell structure, in accordance with some embodiments.

FIG. 5B illustrates an ultra-thick metal (UTM) layer, in accordance with some embodiments.

FIG. 5C illustrates a semiconductor cell structure, in accordance with some embodiments.

FIG. 5D illustrates protecting structures, in accordance with some embodiments.

FIG. 6 illustrates a forming method of a semiconductor cell structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on,” “over,” and the like, may be used herein for ease of description to describe one element or feature's relationship to another element(s) or feature(s), including those illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Source/drain zone(s) may refer to a source or a drain, individually or collectively dependent upon the context.

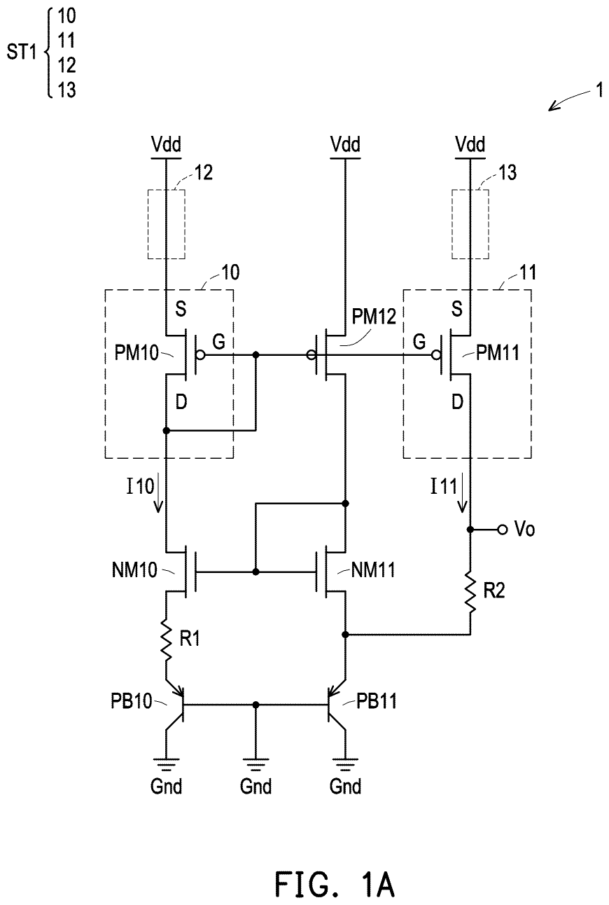

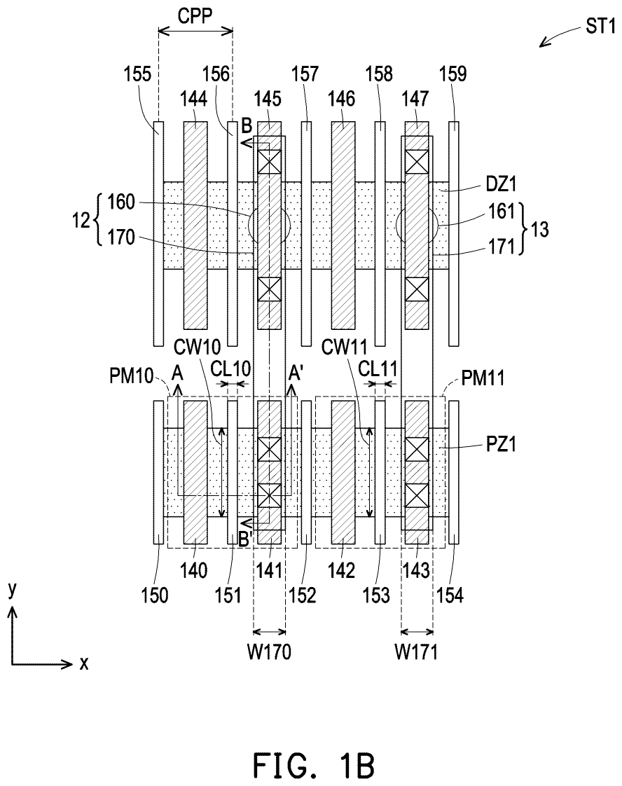

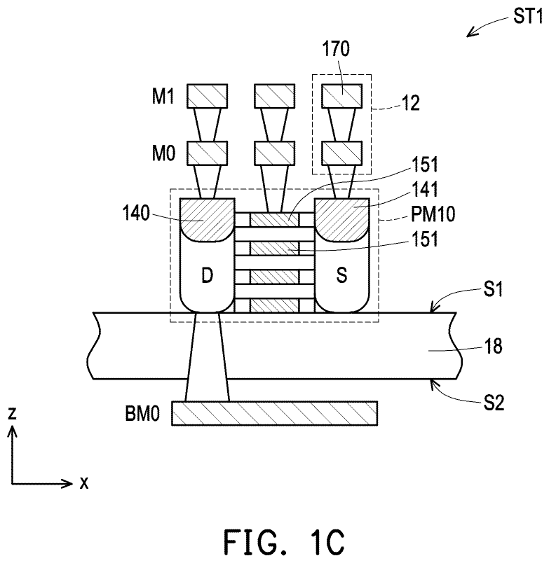

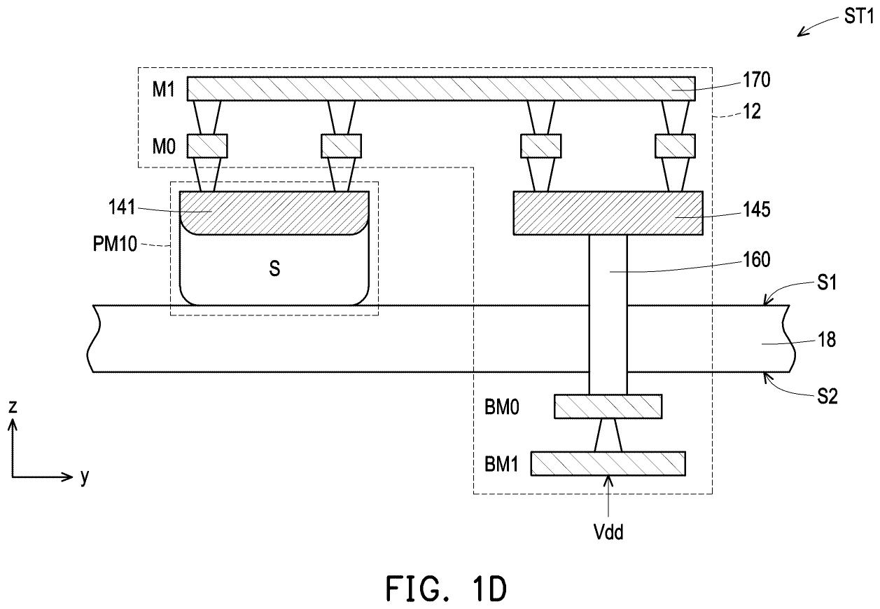

FIG. 1A illustrates a schematic diagram of an integrated circuit 1, in accordance with some embodiments. The integrated circuit 1 is, for example but not limited to, a bandgap circuit utilized for providing an output voltage independent of local temperature variations. For example, the integrated circuit 1 comprises one or more p-type complementary metal-oxide-silicon transistors (PMOS) and one or more n-type complementary metal-oxide-silicon transistors (NMOS). Although not illustrated, transistors of the integrated circuit 1 are disposed on a first surface of a substrate and operated based on an operating voltage Vdd and a ground voltage Gnd received from metal layers below a second surface of the substrate. In other words, the integrated circuit 1 is disposed on a substrate with both sides of the substrate being able to be patterned to dispose semiconductor devices and/or structures for interconnection. The integrated circuit 1 is disposed on the first surface (e.g., a front surface) of the substrate while receiving the operating voltage Vdd and the ground voltage Gnd from metal layers below the second surface (e.g., a back surface) of the substrate. In at least one embodiment, it is possible to achieve one or more advantages including, but not limited to, higher density, smaller area, and lower cost for the integrated circuit 1.

In at least one embodiment, the integrated circuit 1 comprises a reference circuit 10, an output circuit 11, and conductive paths 12 and 13. More particularly, the reference circuit 10 comprises a PMOS PM10 coupled to receive the operating voltage Vdd from a conductive layer (not illustrated) below a back side of the substrate through the conductive path 12. Specifically, the PMOS PM10 is diode connected with its gate and drain coupled together, and its source coupled to the conductive path 12, so the PMOS PM10 outputs a current I10 on its drain. The output circuit 11 also comprises a PMOS PM11 coupled to receive the operating voltage Vdd from the conductive layer below the back side of the substrate through the conductive path 13. Specifically, the gates of the PMOSs PM10, PM11 are coupled together while the PMOSs PM10, PM11 receive the operating voltage Vdd at their sources respectively through the conductive paths 12, 13, so a current I10 conducted at the drain of the PMOS PM10 is mirrored to a current I11 conducted, i.e., provided, at the drain of the PMOS PM11.

In addition to the PMOSs PM10, PM11, the integrated circuit 1 comprises a PMOS P12, NMOSs NM10, NM11, resistors R1, R2, and PNP-type bipolar junction transistors (BJTs) PB10, PB11. The reference circuit 10, the NMOS NM10, the resistor R1, and the BJT PB10 are serially connected between the operating voltage Vdd and the ground voltage Gnd, and biased by the current I10. Moreover, a voltage across the gate-source terminals of the PMOS PM10 of the reference circuit 10 corresponding to the current I10 is generated. A gate voltage Vg of the PMOS PM10 is provided to the output circuit 11, so the current I11 is output on the drain of the PMOS PM11 based on a gate-source voltage of the PMOS PM11. An output signal Vo is generated on a node coupled between the drain of the PMOS PM11 and the resistor R2 by the current I11 flowing through the resistor R2. As a result, the current I11 mirrors the current I10 based on the gate sizes of the PMOSs PM10, PM11, and the currents I10, I11 vary in the same way with respect to temperature changes. In other words, the currents I10, I11 increase or decrease together as the temperature changes. The PMOS PM12 and the NMOS NM11 are serially connected between the operating voltage Vdd and the BJT PB11 to provide another current path to the BJT PB11. The source of the NMOS NM11 is coupled to a bottom end of the resistor R2 (as viewed in FIG. 1A) for providing a voltage that varies inversely with respect to temperature changes at the bottom end of the resistor R2. For example, when the current I11 rises, the PMOS P12 and the NMOS NM11 also lower the voltage at the bottom end of the resistor R2. As such, although the voltage across the resistor R2 is increased by the rise in current I11, the output signal Vo generated on a top end of the resistor R2 is maintained constant and independent with respect to temperature changes.

In the integrated circuit 1, the resistor R2 and the current I11 are selected to achieve voltage variations across the resistor R2 to be equal to voltage variations at the bottom end of the resistor R2, so effects resulting from temperature changes can be mitigated and the output signal Vo can be generated independent from temperature changes. Although the PMOSs PM10, PM11 receive the same gate voltage Vg, the currents I10, I11 may be varied by the source voltages received by the PMOSs PM10, PM11 through the conductive paths 12, 13, since mismatched conductive paths 12, 13 may lead to different source voltages received by the PMOSs PM10, PM11. Therefore, the conductive paths 12, 13 in the integrated circuit 1 are matched, so the PMOSs PM10, PM11 receive the same source voltage through the conductive paths 12, 13. In other words, the same amount of voltage drop is contributed by the matching conductive paths 12, 13.

In an embodiment, a semiconductor cell structure ST1 is formed by the reference circuit 10, the output circuit 11, and the conductive paths 12, 13. The semiconductor cell ST1 is configured to use the current I10 as a reference in order to conduct the current I11. In such embodiment, the reference circuit 10 includes the diode connected PMOS PM10 and the gate voltage Vg is provided to the PMOS PM11 of the output circuit 11. On the other hand, the same voltage, e.g., the operating voltage Vdd, is provided as a reference voltage to the respective sources of the PMOSs PM10, PM11, so the current I11 may be conducted by the PMOS PM11 based on a ratio of an aspect ratio of the PMOS PM10 divided by an aspect ratio of the PMOS PM11. In an embodiment, the aspect ratio of each PMOS or NMNOS is defined as the aspect ratio of the channel of the PMOS or NMOS. The aspect ratio of the channel is determined by dividing a channel width by a channel length. The semiconductor cell structure ST1 may be applied in other integrated circuits, such as current mirrors, voltage-controlled oscillators, delay cells or other suitable circuits which require their internal devices to be matched in currents, voltages, operating frequencies, or other suitable electrical characteristics.

In an embodiment, although the semiconductor cell structure ST1 depicted in FIG. 1A includes the current mirror using the PMOSs PM10 and PM11, other types of current mirrors or transistors may be utilized to replace the semiconductor cell structure ST1 of the integrated circuit 1. Particularly, a circuit configuration of the current mirror formed by NMOSs is similar to that of the current mirror formed by the PMOSs. The circuit configuration of the current mirror formed by NMOSs includes at least two NMOSs, with one NMOS being diode connected. A gate voltage of the diode connected NMOS is shared to the other of the at least two NMOSs, while the same voltage, e.g., the ground voltage Gnd, is provided as a reference voltage to the respective sources of the at least two NMOSs. As such, the current mirror of the semiconductor cell structure ST1 may also be implemented by the NMOSs.

FIG. 1B illustrates a partial layout of the integrated circuit in FIG. 1A including the semiconductor cell structure ST1, in accordance with some embodiments. It is noted that in FIG. 1B, some connections and structures of the semiconductor cell structure ST1 are omitted, and only connections from the PMOSs PM10, PM11 respectively to the conductive paths 12, 13 are illustrated in FIG. 1B. Moreover, in FIG. 1B, elements below a first metal layer for routing are shown in corresponding layout patterns. The elements in FIG. 1B include active zones, dummy zones, gate-strips, conductive segments and other conducting elements (e.g., vias) in a middle layer that is between the first metal layer and the substrate.

In FIG. 1B, the semiconductor cell structure ST 1 includes a p-type active zone PZ1 and a dummy zone DZ1 forming two parallel zones extending in the X-direction. The dummy zone DZ1 is disposed on an upper side of the active zone PZ1 along the Y-direction. The semiconductor cell structure ST1 also includes gate-strips 150-159 extending in the Y-direction that is perpendicular to the X-direction. Each of the gate-strip 150-154 intersects the p-type active zone PZ1 and each of the gate-strip 155-159 intersects the dummy zone DZ1. The semiconductor cell structure ST1 includes conductive segments 140-147 extending in the Y-direction. Each of the conductive segments 140-147 is disposed between two of the gate-strips. For example, the conductive segment 140 is disposed between the gate-strips 150, 151, the conductive segment 141 is disposed between the gate-strips 151, 152, and so on. Each of the conductive segments 140-143 intersects the p-type active zone PZ1 and each of the conductive segments 144-147 intersects the dummy zone DZ1.

In the active zone PZ1, the PMOS PM10 is formed by the two conductive segments 140 and 141 conductively contacting the active zone PZ1 on either side of the gate-strip 151. Similarly, the PMOS PM11 is formed by the two conductive segments 142 and 143 conductively contacting the active zone PZ1 on either side of the gate-strip 153. When a voltage is applied to the gate-strip 151 or 153, a channel is formed under the gate-strip between the adjacent conductive segments. In at least one embodiment, upon a voltage being applied to the gate-strips 151 and 153, the PMOS PM10 has a channel formed under an intersection of the gate-strip 151 and the active zone PZ1, and the PMOS PM11 has a channel formed under an intersection of the gate-strip 153 and the active zone PZ1. The channel provides an electrical connection for the two adjacent conductive segments and is controlled by the voltage applied to the gate-strips. In other words, an electrical characteristic of the channel between drains and sources (e.g., between the conductive segments 140 and 141, and between the conductive segments 142 and 143) is controlled by voltages applied to gates (e.g., the gate-strips 151, 153) of the PMOSs PM10, PM11. For example, conduction states (either being closed and conductive, or being open and nonconductive) or resistances of the PMOSs PM10, PM11 can be controlled based on the voltages applied to the gate-strips 151, 153.

A plurality of dummy MOSs are disposed in the dummy zone DZ1. In some embodiments, gates of the dummy MOSs, e.g., gate strips 156, 157, 158, are floating or coupled to a cutoff voltage for the dummy MOSs to be nonconductive. In addition, vias 160, 161 are disposed within the dummy zone DZ1, respectively under the conductive segments 170, 171. In an embodiment, the gate strips 155-159 disposed in the dummy zone DZ1 are respectively aligned in the Y-direction with the gate strips 150-154 disposed in the active zone PZ1, and the conductive segments 144-147 disposed in the dummy zone DZ1 are respectively aligned in the Y-direction with the conductive segments 140-143 disposed in the active zone PZ1. In an embodiment, the dummy zone DZ1 is formed by dielectric materials for isolating the substrate from voltages on the vias 160, 161.

In at least one embodiment, the channel under the gate strip 151 has a channel width CW10 and a channel length CL10, and the channel under the gate strip 153 has a channel width CW11 and a channel length CL11. Each of the channel widths CW10, CW11 is between about 20 nm and about 90 nm. Each of the lengths is between about 3 nm and about 22 nm. In an embodiment, any two adjacent gate strips are equally spaced with a same pitch distance, which is a Contact Poly Pitch (CPP) as depicted in FIG. 1B. A spacing between centers of any two adjacent vias (e.g., vias 160, 161) is between about 2CPP and about 20 CPP.

More particularly, each of the channels is defined by an area of the corresponding gate strip intersecting the active area. For example, the channel width CW10 and the channel length CL10 of the channel of the PMOS PM10 are defined by an area of the gate strip 151 intersecting the active zone PZ1, and the channel width CW11 and the channel length CL11 of the channel of the PMOS PM11 are defined by an area of the gate strip 153 intersecting the active zone PZ1. Since the active zone PZ1 is rectangular, the channel widths CW10, CW11 of the channels of the PMOSs PM10, PM11 are defined by a width of the active zone PZ1 and are the same. As for the channel lengths CL10, CL11 which are defined by widths of the gate strips 151, 153, each of the gate strips 150-154 may be selected with the same or different widths.

Conducting elements 170, 171 are disposed extending in the Y-direction. The conducting element 170 is disposed above and coupled to the conductive segments 141, 145, and the conducting element 171 is disposed above and coupled to the conductive segments 143, 147. Moreover, vias 160, 161 are respectively disposed under and electrically coupled to the conductive segment 145, 147. Thus, conductive segment 141 is electrically coupled to the via 160 through the conducting element 170 and the conductive segment 145, and the conductive segment 143 is electrically coupled to the via 161 through the conducting element 171 and the conductive segment 147.

As such, the conductive path 12 coupled between the operating voltage Vdd and the source of the PMOS PM10 includes the via 160 and the conducting element 170. The conductive path 12 is coupled between the operating voltage Vdd from a metal layer below a back surface of the substrate and the PMOS PM10. The conductive path 13 coupled between the operating voltage Vdd and the source of the PMOS PM11 includes the via 161 and the conducting element 171.

In an embodiment, the gate strips 150-154 disposed in the active zone PZ1 are selected to have the same width, so the semiconductor cell structure ST1 is easier to integrate into a manufacturing process for standard cells. As such, the PMOSs PM10, PM11 are configured to conduct the same amount of currents I10, I11 since the PMOSs PM10, PM11 have the same channel lengths and the same channel widths. However, to achieve this, in addition to selecting the same channel lengths and the same channel widths for the PMOSs PM10 and PM11, the conductive paths 12, 13 are also selected to have the same shapes or shapes that are symmetrical with each other. Particularly, selecting the same or symmetrical shapes for the conductive paths 12, 13 means that the conducting elements 170, 171 have the same dimensions, and the vias 160, 161 have the same dimensions. As generally illustrated, the conducting elements 170 and 171 are disposed at the same location along the Y-direction, which means that top ends of the conducting elements 170 and 171 are at the same location along the Y-direction, and the bottom ends of the conducting elements 170 and 171 are at same location along the Y-direction. Similarly, corresponding components in the conductive paths 12 and 13 are disposed at the same location along the Y-direction. For example, the vias 160, 161 are at the same position along the Y-direction, and the via (not shown) coupled between the conductive segment 140 and the conducting element 170 and the via (not shown) coupled between the conductive segment 143 and the conducting element 171 are at the same position along the Y-direction. As a result, equivalent impedances of the conductive paths 12, 13 are selected to be the same, so voltage drops across the conductive paths 12, 13 can be equivalent for the PMOSs PM10, PM11 to receive the same voltage at their sources. The same currents I10, I11 are conducted based on the equivalent channel sizes of the PMOSs PM10, PM11 and the equivalent impedances of the conductive paths 12, 13. In other words, the current I10 conducted at the drain of the PMOS PM10 is mirrored to the current I11 conducted at the drain of the PMOS PM11.

In an embodiment, the gate strips 150-154 disposed in the active zone PZ1 are selected to have different widths, causing the channel lengths CL10, CL11 of the PMOS PM10, PM11 to be different. Accordingly, the PMOSs PM10, PM11 are configured for driving different amounts of currents I10, I11 since the respective channels of the PMOSs PM10 and PM11 have different aspect ratios. In order for the currents I10, I11 to be directly proportional to the aspect ratios of the channels of the PMOSs PM10 and PM11, respectively, shapes of the conductive paths 12, 13 are configured to cause the same voltage drops to occur on the conductive paths 12, 13, resulting from the different currents I10. I11, so the PMOSs PM10, PM11 can receive the same voltage on their respective sources. More particularly, the conductive paths 12, 13 may be configured based on the following equations:

$$I 10 \times R 12 = I 11 \times R 13 ,$$

$$\frac{C W 10}{C L 10} \times \frac{1}{W 170} = \frac{C W 11}{C L 11} \times \frac{1}{W 171} ,$$

where R12, R13 respectively denote the equivalent impedances of the conductive paths 12, 13; W170, W171 respectively denote widths of the conducting elements 170, 171; and

$$\frac{C W 10}{C L 10} , \frac{C W 11}{C L 11}$$

respectively denote the aspect ratios of the channels of the PMOSs PM10, PM11. Specifically, the same voltage drops across the conductive paths 12, 13 can be represented as a product of the current I10 multiplied by the equivalent impedance R12 being equal to a product of the current I11 multiplied by the equivalent impedance R13. Further, the currents I10, I11 conducted by the PMOSs PM10, PM11 are respectively directly proportional to the aspect ratios

$$\frac{C W 10}{C L 10} , \frac{C W 11}{C L 11}$$

of the PMOSs PM10, PM11. The equivalent impedances R12, R13 of the conductive paths 12, 13 are respectively proportional to

$$\frac{1}{W 170} , \frac{1}{W 171} .$$

As a result, the voltage drop of the current I10 multiplied by the equivalent impedance R12 can be substituted by

$$\frac{C W 10}{C L 10} \times \frac{1}{W 170} ′ ,$$

and the voltage drop of the current I11 multiplied by the equivalent impedance R13 can be substituted by

$$\frac{C W 11}{C L 11} \times \frac{1}{W 171} .$$

Therefore, a ratio of the aspect ratio

$$\frac{C W 10}{C L 10}$$

of the channel of the PMOS PM10 divided by the width W170 of the conducting element 170 is selected to be equal to a ratio of the aspect ratio

$$\frac{C W 11}{C L 11}$$

of the channel of the PMOS PM11 divided by the width W171 of the conducting element 171 for providing the same voltage drop across the conductive paths 12, 13. In other words, the product of the channel length CL10 multiplied by the width W170 of the conducting element 170 and the product of the channel length CL11 multiplied by the width W171 decrease or increase together. Thus, the product of the channel length CL10 multiplied by the width W170 of the conducting element 170 is positively related to the product of the channel length CL11 multiplied by the width W171.

Assuming that the channel widths CW10 and CW11 are the same due to the rectangular shape of the active zone PZ1, the same voltage drops across the conductive paths 12, 13 can be achieved as long as a product of the channel length CL10 multiplied by the width W170 of the conducting element 170 is equal to a product the product of the channel length CL11 multiplied by the width W171. That is, the same voltage drops across the conductive paths 12, 13 are achieved when the following equation is met:

$$\frac{1}{C L 10 \times W 170} = \frac{1}{C L 11 \times W 171} .$$

Accordingly, the width W171 of the conducting element 171 is inversely proportional to the channel length CL11. For example, as the channel length CL11 decreases, the current I11 to be conducted by the PMOS PM11 is accordingly increased, so the width of the conducting element 171 is correspondingly increased to maintain the same current density on the conducting elements 171, 172, and the same voltage drop across the conductive paths 12, 13.

FIG. 1C illustrates a cross-sectional view of PMOS PM10 along a section line A-A′ in FIG. 1B, in accordance with some embodiments.

As depicted in FIG. 1C, the PMOS PM10 is disposed in a substrate 18. For example, the substrate 18 is a p-type substrate and has opposing surfaces S1, S2. In other embodiments, CMOS structure PM10 may comprise an n-type substrate including one or more p-type wells. In at least one embodiment, semiconductor devices, such as the PMOS and NMOS, and interconnections for them are provided on the surface S1 of the substrate 18. Meanwhile, power, such as the operating voltage Vdd and/or the ground voltage Gnd, are provided from metal layers below the surface S2 of the substrate 18. In at least one embodiment, the PMOS PM11 shown in FIG. 1C can be provided as a gate-all-around (GAA) device, and the PMOS PM10 can also be provided as a GAA device.

More particularly, the PMOS PM10 is disposed on the surface S1 of the substrate 18 with its drain, gate, and source respectively coupled to the conductive segment 140, the gate-strip 150, and the conductive segment 141. In at least one embodiment, the PMOS PM10 is a gate-all-around transistor device having a plurality of nanowires or nanosheet connected to the source and drain. The gate of the PMOS PM10 further includes an oxide layer formed by a dielectric material comprising HfO₂, LaO, AlO, ZrO, TiO, Ta₂O₅, Y₂O₃, SrTiO₃ (STO), BaTiO₃(BTO), BaZrO, HfZrO, HfLaO, HfSiO, LaSiO, AlSiO, HfTaO, HfTiO, (Ba, Sr)TiO₃ (BST), Al₂O₃, Si₃N₄, silicon oxynitrides (SiOₓN_{y}), or the like. In addition, metal layers M0, M1 are disposed above the PMOS PM10 for providing electrical connections for semiconductor devices on the surface S1, while metal layer BM0 (e.g., a conductive layer) is disposed the surface S2 of the substrate 18 for providing connections to power. The metal layers metal layers M0, M1, BM0 may comprise Ti, Ag, Al, TiAlN, TaC, TaCN, TaSiN, Mn, Zr, TiN, TSN, TaN, Ru, Mo, Al, WN, Cu, W, or the like. Further, the source of the PMOS PM10 is coupled to the conductive path 12, implemented by the metal layers M0, M1 above the surface S1 of the substrate 18, through the conductive segment 141 for receiving the operating voltage Vdd.

FIG. 1D illustrates a cross-sectional view of the conductive path 12 along a section line B-B′ in FIG. 1B, in accordance with some embodiments.

The conductive path 12 includes the conducting element 170 and the via 160. The conducting element 170 is implemented by the metal layers M0, M1 above the surface S1. The conducting element 170 extends in the Y-direction. Further, the conducting element 170 also extends in the Z-direction and is coupled between the conductive segments 141, 145. The via 160 extends in the Z-direction from above the surface S1 to below the surface S2, for coupling the operating voltage Vdd received from a metal layer BM1 below the surface S2 of the substrate 18 to the conductive segment 145 above the surface S1 of the substrate 18. As a result, the PMOS PM10 receives the operating voltage Vdd provided from a metal layer below the surface S2 through the conductive path 12.

Although not illustrated, the conductive path 13 has the same shape or structure as the conductive path 12. More particularly, the conductive path 13 includes the conducting element 171 and the via 161. The conducting element 171 extends in the Y-direction. Further, the conducting element 171 also extends in the Z-direction and is coupled between the conductive segments 143, 147. The via 161 extends from above the surface S1 of the substrate 18 to below the surface S2 of the substrate 18, for transmitting the operating voltage Vdd from a metal layer below the surface S2 to the conductive segment 147 above the surface S1. As a result, the PMOS PM11 receives the operating voltage Vdd provided from a metal layer below the surface S2 through the conductive path 13.

Since the structures of the conductive paths 12, 13 are the same, equivalent impedances of the conductive paths 12, 13 are matched for the PMOSs 12, 13 to receive the same voltage on their respective sources from the conducting elements 170, 171. Moreover, since the gate-source voltages received by the PMOSs PM10, PM11 are the same, the matched conductive paths 12, 13 not only enable the source voltages of the PMOSs PM10, PM11 to be the same, but also control the currents I10, I11 output by the PMOSs PM10, PM11 to be accurately based on the gate sizes of the PMOSs PM10, PM11. More particularly, an output current of a NMOS or a PMOS is proportional to a ratio of width over length of its channel. Thus, in the exemplary embodiment depicted in FIG. 1B in which the PMOSs PM10, PM11 have substantially the same channel widths and channel lengths, the currents I10, I11 output by the PMOSs PM10, PM11 are substantially the same, provided the PMOSs PM10, PM11 receive the same gate and source voltages. Therefore, by providing the conductive paths 12, 13 matched in the semiconductor cell structure ST1, the same source voltages may be provided to the PMOSs PM10, PM11 to ensure the output currents I10, I11 are the same, thereby improving stability of the output signal Vo with respect to temperature changes.

Although the exemplary embodiment illustrated by the semiconductor cell structure ST1 is a bandgap circuit, the concept of providing the same voltages to the reference circuit and the output circuit through matched conductive paths may be implemented in other designs to achieve accurate impedance matching, such as in current mirror, differential amplifier, delay cells, etc.

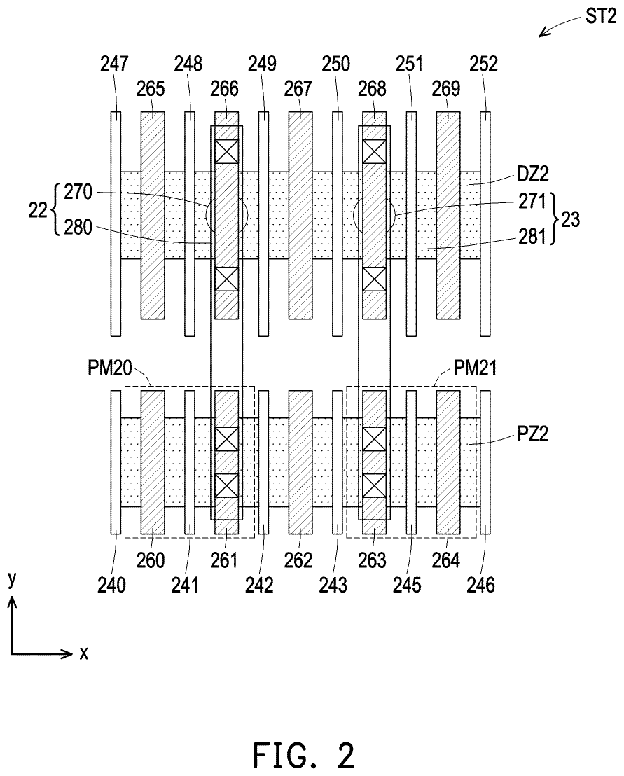

FIG. 2 illustrates a layout of a semiconductor cell structure ST2, in accordance with some embodiments. In FIG. 2, PMOSs PM20, PM21 and conductive paths 22, 23 are depicted. FIG. 2 particularly depicts connections from the PMOS PM20 to the conductive path 22, and from the PMOS PM21 to the conductive path 23 while some connections, such as connections to gates and drains of the PMOSs PM20, PM21, are not shown for clarity. In at least one embodiment, the layout depicted in FIG. 2 may serve as a layout for implementing part of the circuits of the semiconductor cell structure ST1 in FIG. 1A. For example, the PMOSs PM10, PM11 and the conductive paths 12, 13 in FIG. 1A may be implemented by the PMOSs PM20, PM21 and the conductive paths 22, 23 in FIG. 2.

In FIG. 2, the semiconductor cell structure ST2 includes a p-type active zone PZ2 and a dummy zone DZ2 forming two parallel zones extending in the X-direction. The semiconductor cell structure ST1 includes gate-strips 240-252 extending in the Y-direction that is perpendicular to the X-direction. Each of the gate-strip 240-246 intersects the p-type active zone PZ2 and each of the gate-strip 247-252 intersects the dummy zone PZ2. The semiconductor cell structure ST2 includes conductive segments 260-269 extending in the Y-direction. Each of the conductive segments 260-269 is disposed between two gate-strips.

In the active zone PZ2, the PMOS PM20 is formed by the two conductive segments 260 and 261 conductively contacting the active zone PZ2 on either side of the gate-strip 241. Similarly, the PMOS PM21 is formed by the two conductive segments 263 and 264 conductively contacting the active zone PZ2 on either side of the gate-strip 245.

Conducting elements 280, 281 are disposed extending in the Y-direction. The conducting element 280 is disposed above and coupled to the conductive segments 261, 266, and the conducting element 281 is disposed above and coupled to the conductive segments 263, 268. Moreover, vias 270, 271 are respectively disposed under and electrically coupled to the conductive segment 266, 268. Thus, conductive segment 261 is electrically coupled to the via 270 through the conducting element 280, and the conductive segment 263 is electrically coupled to the via 271 through the conducting element 281. Details regarding the PMOSs PM20, PM21 and conductive paths 22, 23 are substantially the same as described above for the PMOSs PM10, PM11 and conductive paths 12, 13 with reference to FIG. 1B, and are not repeated herein.

In the semiconductor cell structure ST2, the PMOSs PM20, PM21 are symmetrically disposed, along with the conductive paths 22, 23. Sizes of channels of the PMOSs PM20, PM21 are the same but have opposite orientations. More particularly, the conductive path 22, including the conducting element 280 and the via 270, is disposed on the right hand-side of the PMOS PM20, while the conductive path 23 is disposed on left-hand side of the PMOS PM21. As a result, through symmetrically disposing the PMOSs PM20, PM21 and the conductive paths 22, 23, impedance matching between the conductive paths 22, 23 is maintained while reducing design complexity of the semiconductor cell structure ST2.

In at least one embodiment, it is possible to achieve one or more advantages including, but not limited to, better impedance matching and simpler layout complexity. In addition, in order to maintain spacing between any two adjacent vias (e.g., vias 270, 271) between substantially 2 CPP and substantially 20 CPP, dummy gate-strips 242, 243 and dummy conductive segment 262 are disposed between the PMOSs PM20, PM21.

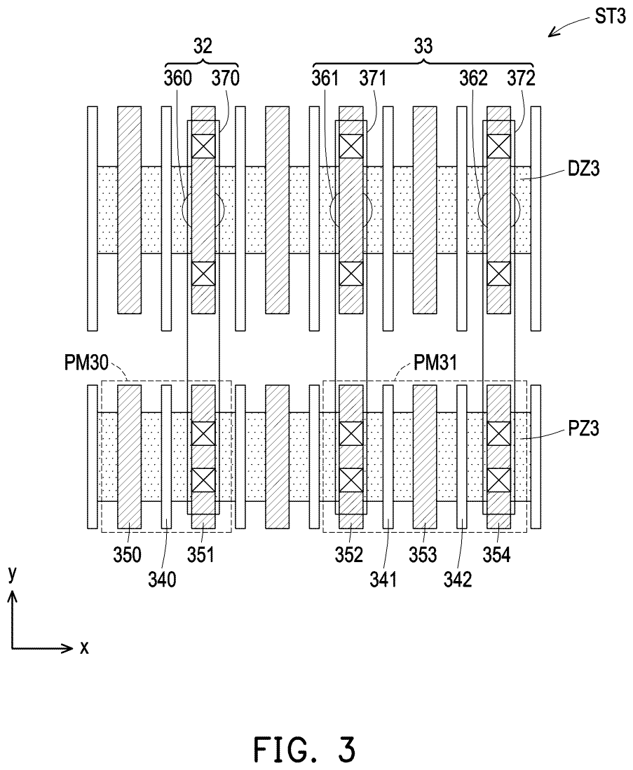

FIG. 3 illustrates a layout of a semiconductor cell structure ST3, in accordance with some embodiments. In FIG. 3, PMOSs PM30, PM31 and conductive paths 32, 33 are depicted. FIG. 3 particularly depicts connections from the PMOS PM30 to the conductive path 32, and from the PMOS PM31 to the conductive path 33 while some other connections, such as connections to gates and drains of the PMOSs PM30, PM31, are not shown for clarity. In at least one embodiment, the layout depicted in FIG. 3 may serve as a layout for implementing part of the circuits of the semiconductor cell structure ST1 in FIG. 1A. For example, the PMOSs PM10, PM11 and the conductive paths 12, 13 in FIG. 1A may be implemented by the PMOSs PM30, PM31 and the conductive paths 32, 33 in FIG. 3.

In FIG. 3, the semiconductor cell structure ST3 includes a p-type active zone PZ3 and a dummy zone DZ3 forming two parallel zones extending in the X-direction. The semiconductor cell structure ST3 includes gate-strips 340-342 extending in the Y-direction that is perpendicular to the X-direction. Each of the gate-strip 340-342 intersects the p-type active zone PZ3. The semiconductor cell structure ST3 includes conductive segments 350-354 extending in the Y-direction. Each of the conductive segments 350-354 is disposed between two gate-strips.

In the active zone PZ3, the PMOS PM30 is formed by two conductive segments 350 and 351 conductively contacting the active zone PZ3 on either side of the gate-strip 340. However, the PMOS PM31 is formed by three conductive segments 352-354 conductively contacting the active zone PZ3 with the gate-strip 341 between the conductive segments 352 and 353, and the gate-strip 342 between the conductive segments 353 and 354.

Three vias 360-362 are disposed in the dummy zone DZ3. Conducting elements 370-372 are disposed extending in the Y-direction. The conducting elements 370-372 provide an electrical connection respectively from the conductive segments 351, 352, 354 to the vias 360-362. Details regarding the PMOSs PM30, PM31 and conductive paths 32, 33 are substantially the same as described above for the PMOSs PM10, PM11 and conductive paths 12, 13 with reference to FIG. 1B, and are not repeated herein.

In FIG. 3, the PMOS PM31 is formed by equivalently coupling two sub-transistors in parallel. More particularly, the conductive segments 352, 354 serve as sources of the sub-transistors while the conductive segment 353 serve as a drain shared by the sub-transistors. Provided that widths and lengths of the gate-strips 340-342 are equal, an equivalent channel width of the PMOS PM31 is twice that of the PMOS PM30, resulting in a ratio of width to length of the channel of the PMOS PM31 being twice that of the PMOS PM30. In other words, when the PMOSs PM30, PM31 receive the same gate-source voltages, the current driven by the PMOS PM31 is approximately twice the current driven by the PMOS PM30 since the driven current of each MOS is proportional to a ratio of width-to-length of its channel.

In at least one embodiment, sizes of the conducting elements 370-372 are the same (either their widths or lengths), and sizes of the vias 360-362 are also the same. Two conducting elements 371, 372 are disposed respectively between the conductive segment 352 and the via 361, and between the conductive segment 354 and the via 362. Therefore, the via 361 and the conducting elements 371 are coupled in parallel to the via 362 and the conducting elements 372, resulting in an equivalent impedance of the conductive path 33 being one-half that of the conductive path 32. However, the same voltage drops occur on the conductive paths 32, 33, since the current driven by the PMOS PM31 is twice that of the PMOS PM30. Therefore, by selecting an equivalent impedance of the conductive path to be inversely proportional to a ratio of a width over length of a corresponding MOS channel, the same voltage drop on each conductive path is achieved, thereby reducing mismatches for the semiconductor cell structure ST3.

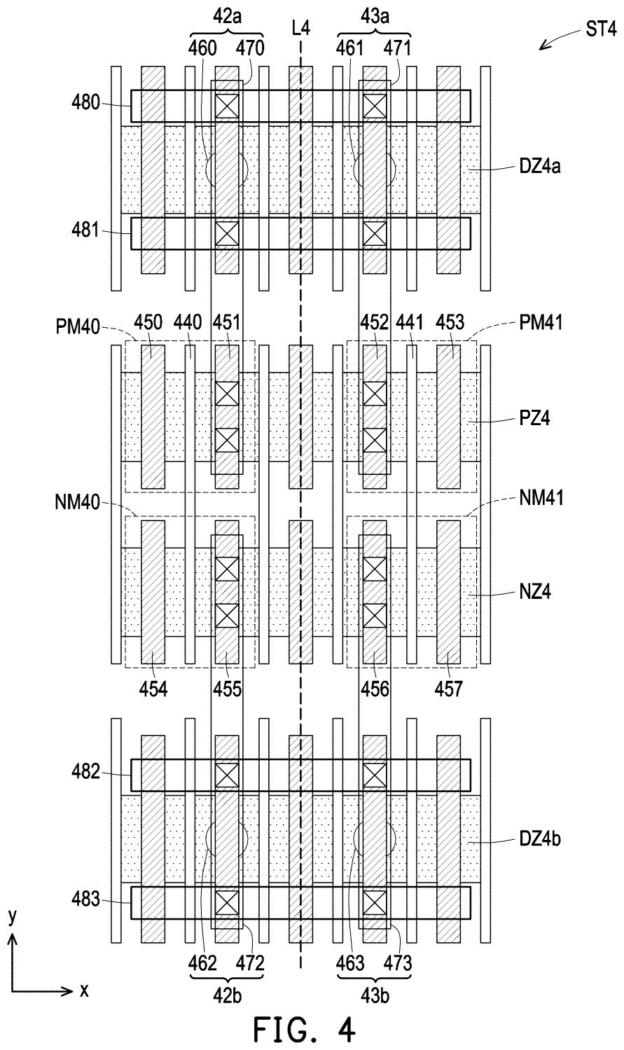

FIG. 4 illustrates a layout of a semiconductor cell structure ST4, in accordance with some embodiments. Details regarding PMOSs PM40, PM41 and conductive paths 42a, 43a shown in FIG. 4 are substantially the same as described above for the PMOSs PM20, PM21 and conductive paths 22, 23 with reference to FIG. 2, and are not repeated herein. In at least one embodiment, the layout as depicted in FIG. 4 may serve as a layout for implementing part of the circuits of the semiconductor cell structure in FIG. 1A. For example, the PMOSs PM10, PM11 and the conductive paths 12, 13 in FIG. 1A may be implemented by the PMOSs PM40, PM41 and the conductive paths 42a, 43a in FIG. 4.

In addition to a P-type active zone PZ4 and a dummy zone DZ4a, the semiconductor cell structure ST4 includes an N-type active zone NZ4 and a dummy zone DZ4b. NMOSs NM40, NM41 are disposed in the active zone NZ4. In at least one embodiment, the dummy zones DZ4a, DZ4b are for transmitting different voltages. For example, vias 460, 461 disposed in the dummy zone DZ4a provide connections from the operating voltage Vdd to the PMOSs PZ40, PM41. On the other hand, vias 462, 463 disposed in the dummy zone DZ4b provide connections from the ground voltage Gnd to the NMOSs NM40, NM41.

In at least one embodiment, the dummy zone DZ4a is disposed on a upper side of the active zone PZ4 along the Y-direction and the dummy zone DZ4b is disposed on a lower side of the active zone NZ4 along the Y-direction. The active zone PZ4 is disposed between the dummy zone DZ4a and the active zone NZ4, and the active zone NZ4 is disposed between the active zone PZ4 and the dummy zone DZ4b. By providing the P-type active zone PZ4 adjacent to the dummy zone DZ4a and the N-type active zone NZ4 adjacent to the dummy zone DZ4b, unnecessary routing can be reduced since the operating voltage Vdd is more likely to be required by the PMOSs, and the ground voltage is more likely to be required by the NMOSs.

In at least one embodiment, the semiconductor cell structure ST4 further comprises power rails 480-483 extending in the X-direction and conducting elements 470-473 extending in the Y-direction. The power rails 480-483 are disposed in a metal layer above the conducting elements 470-473. More particularly, the power rails 480, 481 are disposed above the dummy zone DZ4a and coupled to the conducting elements 470, 471, and the power rails 482, 483 are disposed above the dummy zone DZ4b and coupled to the conducting elements 472, 473. That is, the power rails are coupled to the conducting elements transmitting the same voltage to facilitate voltage regulation.

In the semiconductor cell structure ST4, in order for the equivalent impedances of the conductive paths 42a, 43a to be the same, the power rails 480, 481 are disposed symmetrically about a line IA that is a perpendicular bisector of the PMOSs PM40, PM41. As such, the symmetry of the power rails 480, 481 ensures that the equivalent impedances of the conductive paths 42a, 43a match and the PMOSs PM40, PM41 receive the same voltage respectively through the conductive paths 42a, 43a. Similarly, the power rails 482, 483 are also symmetric about the conductive paths 42a, 43a since the line L4 is also the perpendicular bisector of the NMOSs NM40, NM41.

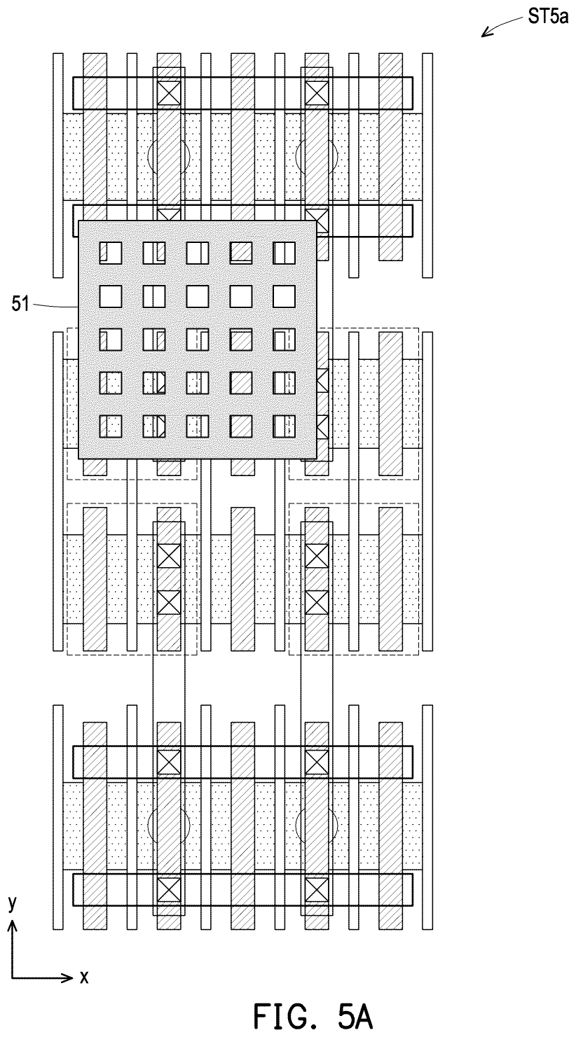

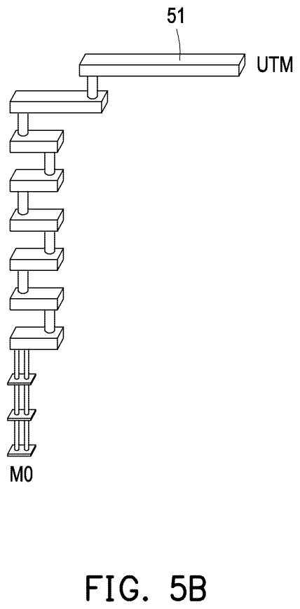

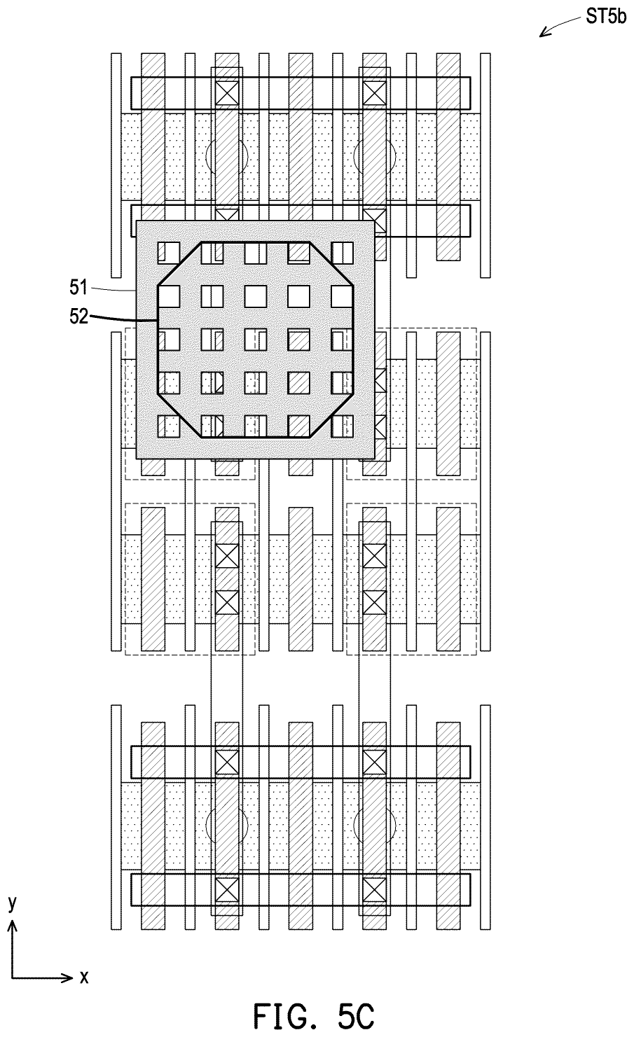

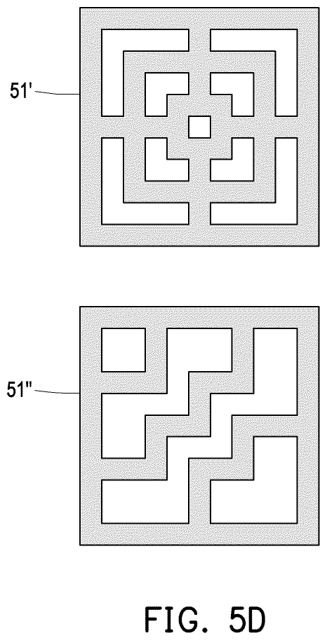

FIG. 5A illustrates a semiconductor cell structure ST5a, in accordance with some embodiments. The semiconductor cell structure ST5a is similar to the semiconductor cell structure ST4 and includes PMOSs PM40, PM41 and conductive paths 42a, 43a, except that the semiconductor cell structure ST5a further includes a protecting structure 51. In at least one embodiment, the layout as depicted in FIG. 5A may serve as a layout for implementing part of the circuits of the semiconductor cell structure ST1 in FIG. 1A. For example, the PMOSs PM10, PM11 and the conductive paths 12, 13 in FIG. 1A may be implemented by the PMOSs PM40, PM41 and the conductive paths 42a, 43a in FIG. 5A.

FIG. 5B illustrates an ultra-thick metal (UTM) layer, in accordance with some embodiments. In an embodiment, the protecting structure 51 is realized on a metal layer, for example, a UTM layer, above the PMOS PM40 or PM41. As can be seen in FIG. 5B, the UTM layer may be coupled to the metal layer M0 through intermediate vias and metal layers. In at least one embodiment, the protecting structure 51 is realized using a mesh structure as depicted in FIG. 5A and is coupled together as an integrated structure. As such, the protecting structure 51 is able to minimize stress applied to the semiconductor cell structure ST5a. In at least one embodiment, when a stress is applied to the semiconductor device 5a, structures of the PMOSs PM40, PM41 and the conductive paths 42a, 43a are affected, and thus mismatches in operating characteristics occur. In order to reduce mismatches caused by stress, the protecting structure 51 may be disposed to cover the semiconductor cell structure ST5a.

FIG. 5C illustrates a semiconductor cell structure ST5b, in accordance with some embodiments. The semiconductor cell structure ST5b is similar to the semiconductor cell structure ST5a except that the semiconductor cell structure ST5b further includes a conductive pad 52 on the protecting structure 51. More particularly, the conductive pad 52 may be a bonding pad utilized for receiving input/output signals. In at least one embodiment, an area of the protecting structure 51 having larger than or equal to an area of the conductive pad 52, so an external stress applied on the conductive pad 52 may be dissipated by the protecting structure 51 having a larger size in order to protect the PMOSs PM40, PM41 underneath. The protecting structure 51 disposed between the conductive pad and the PMOSs PM40, PM41 disperses stress applied on the PMOSs PM40, PM41, thereby reducing mismatches in operating characteristics that may result from the stress.

In at least one embodiment, the conductive pad 52 and the protecting structure 51 are disposed on a back side of the substrate. For example, the conductive pad 52 may be utilized for transmitting power and disposed on the backside of the substrate. Since the conductive pad 52 overlaps the PMOSs PM40, PM41 on another side of the substrate, the stress applied from the conductive pad 52 also degrades performance of the semiconductor device 5b. Therefore, the protecting structure 51 may be disposed on the backside and between the conductive pad 52 and the PMOSs PM40 or PM41.

FIG. 5D illustrates exemplary protecting structures 51′, 51″, in accordance with some embodiments. Each of the protecting structure 51′, 51″ may be implemented in the semiconductor cell structures ST5a, 5b to replace the protecting structure 51. More particularly, the protecting structure 51′ is formed by different sizes of squares, and the protecting structure 51″ is formed by a zig-zag structure. Different shapes are also within the scope of various embodiments.

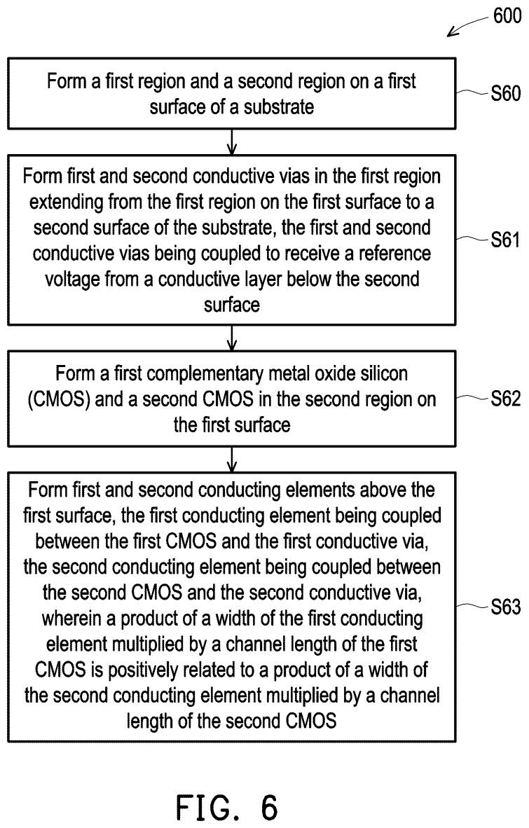

FIG. 6 illustrates a method 600 for manufacturing semiconductor cell structure, in accordance with some embodiments. The manufacturing method 600 may be utilized to form any one of the semiconductor cell structures 1, 2, 3, 4, 5a, 5b as depicted in FIGS. 1A-1C, 2, 3, 4, 5A, 5C. The manufacturing method 600 includes steps S60-S63.

In step S60, a first region and a second region are formed on a first surface of a substrate. For example, the first region may be any one of the dummy regions DZ1, DZ2, DZ3, DZ4a, DZ4b as depicted FIGS. 1B and 2-4, and the second region may be any one of the active regions PZ1, PZ2, PZ3, PZ4, NZ4 as depicted FIGS. 1B, 2-4. In at least one embodiment, the first region is formed by dielectric materials for isolating voltages from the substrate.

In step S61, first and second conductive vias are formed in the first region. The first and second conductive vias extend from the first region on the first surface to a second surface opposite to the first surface of the substrate. More particularly, the first and second conductive vias disposed in the dummy region are configured to provide a reference voltage from a conductive layer below the second surface to the first surface.

In step S62, a first CMOS and a second CMOS are formed in the second region on the first surface. In at least one embodiment, the first CMOS and the second CMOS are configured to conduct currents respectively corresponding to aspect ratios of their channel.

In step S63, a first conducting element and a second conducting element are formed above the first surface. The first conducting element is coupled between the first CMOS and the first conductive via. The second conducting element is coupled between the second CMOS and the second conductive via. Therefore, a first conductive path comprising the first conductive via and the first conducting element, and a second conductive path comprising the second conductive via and the second conducting element are formed. In order for the first CMOS and the second CMOS to conduct the currents respectively corresponding to the aspect ratios of their channels, the first CMOS and the second CMOS receive substantially the same voltage from the first conductive path and the second conductive path.

More particularly, the first conducting element and the second conducting element are selected to result in a ratio of the aspect ratio of the channel of the first CMOS divided by the width of the conducting element equal to a ratio of the aspect ratio of the channel of the second CMOS divided by the width of the second conducting element, so the same voltage drops across the first conductive path and the second conductive path are provided. Further, provided that the channel widths of the first CMOS and the second CMOS are the same, the same voltage drops across the first and second conductive paths can be achieved as long as a product of the channel length of the first CMOS multiplied by the width of the first conducting element is equal to a product of the channel length of the second CMOS multiplied by the width of the second conducting element. The width of the second conducting element is inversely proportional to the channel length of the second CMOS. For example, as the channel length of the second CMOS decreases, the current to be conducted by the second CMOS PM11 is accordingly increased, so the width of the second conducting element is correspondingly increased to provide the same voltage drops across the conductive paths 12, 13.

In an embodiment, a semiconductor cell structure is disposed on a substrate having a first surface and a second surface opposite to the first surface. The semiconductor cell structure comprises a first CMOS, a second CMOS, a first conductive path, and a second conductive path. The first CMOS is disposed in a first region on the first surface of the substrate. The second CMOS is disposed in the first region on the first surface of the substrate. The first conductive path comprises a first conductive via and a first conducting element. The first conductive via extends from a second region on the first surface to the second surface of the substrate. The first conductive via is coupled to receive a reference voltage from a conductive layer below the second surface of the substrate. The first conducting element is coupled between the first CMOS and the first conductive via above the first surface. The second conductive path comprises a second conductive via and a second conducting element. The second conductive via extends from the second region on the first surface to the second surface of the substrate. The second conductive via is coupled to receive the reference voltage from the conductive layer below the second surface of the substrate. The second conducting element is coupled between the second CMOS and the second conductive via above the first surface. A product of a width of the first conducting element multiplied by a channel length of the first CMOS is positively related to a product of a width of the second conducting element multiplied by a channel length of the second CMOS.

In an embodiment, an integrated circuit comprises a substrate and a semiconductor cell structure. The substrate has a first surface and a second surface opposite to the first surface. The semiconductor cell structure comprises a first CMOS, a second CMOS, a first conductive path, and a second conductive path. The first CMOS is disposed in a first region on the first surface of the substrate. The second CMOS is disposed in the first region on the first surface of the substrate. The first conductive path comprises a first conductive via and a first conducting element. The first conductive via extends from a second region on the first surface to the second surface of the substrate. The first conductive via is coupled to receive a reference voltage from the conductive layer below the second surface of the substrate. The first conducting element is coupled between the first CMOS and the first conductive via above the first surface. The second conductive path comprises a second conductive via and a second conducting element. The second conductive via extends from the second region on the first surface to the second surface of the substrate. The second conductive via is coupled to receive the reference voltage from the conductive layer below the second surface of the substrate. The second conducting element is coupled between the second CMOS and the second conductive via above the first surface. A product of a width of the first conducting element multiplied by a channel length of the first CMOS is positively related to a product of a width of the second conducting element multiplied by a channel length of the second CMOS.

In an embodiment, a manufacturing method comprises forming a first region and a second region on a first surface of a substrate; forming first and second conductive vias in the first region extending from the first region on the first surface to a second surface of the substrate, the first and second conductive vias being coupled to receive a reference voltage from the conductive layer below the second surface; forming a first CMOS and a second CMOS in the second region on the first surface; and forming first and second conducting elements above the first surface, the first conducting element being coupled between the first CMOS and the first conductive via, the second conducting element being coupled between the second CMOS and the second conductive via. A product of a width of the first conducting element multiplied by a channel length of the first CMOS is positively related to a product of a width of the second conducting element multiplied by a channel length of the second CMOS.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor cell structure disposed on a substrate having a first surface and a second surface opposite to the first surface, the semiconductor cell structure comprising:
a first complementary metal oxide silicon (CMOS) disposed in a first region on the first surface of the substrate;
a second CMOS disposed in the first region on the first surface of the substrate;
a first conductive path comprising:
a first conductive via extending from a second region on the first surface to the second surface of the substrate, the first conductive via being coupled to receive a reference voltage from a conductive layer below the second surface of the substrate; and
a first conducting element, coupled between the first CMOS and the first conductive via, above the first surface; and
a second conductive path comprising:
a second conductive via extending from the second region on the first surface to the second surface of the substrate, the second conductive via being coupled to receive the reference voltage from the conductive layer below the second surface of the substrate; and
a second conducting element, coupled between the second CMOS and the second conductive via, above the first surface,
wherein a product of a width of the first conducting element multiplied by a channel length of the first CMOS is positively related to a product of a width of the second conducting element multiplied by a channel length of the second CMOS.

2. The semiconductor cell structure of claim 1, wherein a drain and a gate of the first CMOS are coupled together, and the gate of the first CMOS is coupled to a gate of the second CMOS.

3. The semiconductor cell structure of claim 1, wherein sources of the first CMOS and the second CMOS are respectively coupled to the first conductive path and the second conductive path, the first CMOS and the second CMOS receiving substantially the same voltage from the first conductive path and the second conductive path.

4. The semiconductor cell structure of claim 1, wherein voltage drops across the first conductive path and the second conductive path are substantially the same.

5. The semiconductor cell structure of claim 1, wherein the first CMOS and the second CMOS are gate-all-around (GAA) devices.

6. The semiconductor cell structure of claim 1, wherein the first conducting element and the second conducting element have shapes that are symmetrical with each other or the same.

7. The semiconductor cell structure of claim 1, wherein channel widths of the first CMOS and the second CMOS are defined by a width of the first region, the channel width of the first CMOS being substantially the same as the channel width of the second CMOS.

8. The semiconductor cell structure of claim 1, wherein a ratio of an aspect ratio of the channel of the first CMOS to the width of the first conducting element is equal to a ratio of an aspect ratio of the channel of the second CMOS to the width of the second conducting element.

9. The semiconductor cell structure of claim 1, wherein a channel width of the first CMOS is between about 20 nm and about 90 nm, and a channel length of the first CMOS is between about 3 nm and about 22 nm.

10. An integrated circuit, comprising:
a substrate having a first surface and a second surface opposite to the first surface; and
a semiconductor cell structure comprising:
a first complementary metal oxide silicon (CMOS) disposed in a first region on the first surface of the substrate;
a second CMOS disposed in the first region on the first surface of the substrate;
a first conductive path comprising:
a first conductive via extending from a second region on the first surface to the second surface of the substrate, the first conductive via being coupled to receive a reference voltage from a conductive layer below the second surface of the substrate; and
a first conducting element, coupled between the first CMOS and the first conductive via, above the first surface; and
a second conductive path comprising:
a second conductive via extending from the second region on the first surface to the second surface of the substrate, the second conductive via being coupled to receive the reference voltage from the conductive layer below the second surface of the substrate; and
a second conducting element, coupled between the second CMOS and the second conductive via, above the first surface,
wherein a product of a width of the first conducting element multiplied by a channel length of the first CMOS is positively related to a product of a width of the second conducting element multiplied by a channel length of the second CMOS.

11. The integrated circuit of claim 10, wherein the semiconductor cell structure is a first semiconductor cell structure, the first CMOS and the second CMOS are P-type CMOSs, the integrated circuit further comprising:
a second semiconductor cell structure comprising:
a third CMOS disposed in a third region on the first surface of the substrate; and
a fourth CMOS disposed in the third region on the first surface of the substrate,
wherein the third CMOS and the fourth CMOS are N-type CMOSs, and the second region and third region are on opposite sides of the first region.

12. The integrated circuit of claim 11, wherein the reference voltage is a first reference voltage, the second semiconductor cell structure comprising:
a third conductive path comprising:
a third conductive via extending from a fourth region on the first surface to the second surface of the substrate, the third conductive via being coupled to receive a second reference voltage from the conductive layer below the second surface; and
a third conducting element, coupled between the third CMOS and the third conductive via, above the first surface; and
a fourth conductive path comprising:
a fourth conductive via extending from the fourth region on the first surface to the second surface of the substrate, the fourth conductive via being coupled to receive the second reference voltage from the conductive layer below the second surface; and
a fourth conducting element, coupled between the fourth CMOS and the fourth conductive via, above the first surface,
wherein a product of a width of the third conducting element multiplied by a channel length of the third CMOS is equal to a product of a width of the fourth conducting element multiplied by a channel length of the fourth CMOS.

13. The integrated circuit of claim 12, wherein the first region and the fourth region are disposed on opposite sides of the third region.

14. The integrated circuit of claim 10, further comprising a protecting structure overlapping at least one of the first CMOS and the second CMOS.

15. The integrated circuit of claim 14, wherein the protecting structure comprises an ultra-thick metal (UTM) layer.

16. The integrated circuit of claim 14, further comprising a conductive pad overlapping the protecting structure, an area of the conductive pad being less than or equal to an area of the protecting structure.

17. A manufacturing method of a semiconductor cell, the manufacturing method comprising:
forming a first region and a second region on a first surface of a substrate;
forming first and second conductive vias in the first region extending from the first region on the first surface to a second surface of the substrate, the first and second conductive vias being coupled to receive a reference voltage from a conductive layer below the second surface;
forming a first complementary metal oxide silicon (CMOS) and a second CMOS in the second region on the first surface; and
forming first and second conducting elements above the first surface, the first conducting element being coupled between the first CMOS and the first conductive via, the second conducting element being coupled between the second CMOS and the second conductive via,
wherein a product of a width of the first conducting element multiplied by a channel length of the first CMOS is positively related to a product of a width of the second conducting element multiplied by a channel length of the second CMOS.

18. The manufacturing method of claim 17, wherein the first CMOS and the second CMOS receive substantially the same voltage from the first conducting element and the second conducting element.

19. The manufacturing method of claim 17, wherein the first conducting element and the second conducting element are formed to have shapes that are symmetrical with each other or the same.

20. The forming method of claim 17, further comprising forming a first conductive path including the first conducting element and the first conductive via, and forming a second conductive path including the second conducting element and the second conductive via,
wherein voltage drops across the first conductive path and the second conductive path are substantially the same.
